(19) United States
(12) Patent Application Publication
(10) Pub. No.: US 2014/0159062 A1
(43) Pub. Date: Jun. 12, 2014

(54) OPTICAL COUPLING DEVICE

(71) Applicant: Renesas Electronics Corporation, Kanagawa (JP)

(72) Inventor: Yukio NOMURA, Kanagawa (JP)

(73) Assignee: Renesas Electronics Corporation, Kanagawa (JP)

(21) Appl. No.: 14/102,784

(22) Filed: Dec. 11, 2013

(30) Foreign Application Priority Data
Dec. 11, 2012 (JP) 2012-270807
Sep. 18, 2013 (JP) 2013-193141

(51) Int. Cl. H01L 31/12

(52) U.S. Cl. CPC H01L 31/125
USPC 257/84

(57) ABSTRACT

A optical coupling device includes a first lead frame; a light emitting device installed on the first lead frame; a light receiving device configured to receive an optical signal outputted from the light emitting device; a translucent silicon-based resin layer which covers the light emitting device; and a conductive wire connecting the first lead frame and the light emitting device. The conductive wire is formed of a material which contains silver.

### CROSS-REFERENCE

This patent application claims priorities on convention based on Japanese Patent Applications JP 2012-270807 and JP 2013-193141. The disclosures thereof are incorporated herein by reference.

### TECHNICAL FIELD

The present invention relates to an optical coupling device.

### BACKGROUND ART

Optical coupling devices, which are exemplified as a photo coupler and an optical MOSFET, are known. The optical coupling device has a light emitting device and a light receiving device. In the optical coupling device, an electrical signal is converted into an optical signal by the light emitting device. The optical signal is supplied to the light receiving device. When receiving the optical signal, the light receiving device becomes an electrically conductive state. Consequently, while an electrically insulating state between the light emitting device and the light receiving device is kept, a signal can be transferred.

As one example of the optical coupling devices, an optical coupling device disclosed in Patent Literature 1 (JP H10-209488A) is known. In the optical coupling device of the Patent Literature 1, the light emitting device is disposed on a primary side lead frame and wire-bonded to a wiring lead frame and the light receiving device is disposed on a secondary side lead frame and wire-bonded to a wiring lead frame. The light emitting device and the light receiving device are covered with a primary translucent mold such as epoxy resin, and in this periphery, a secondary molding layer which is made of light-blocking epoxy resin and the like is formed. Note that the light emitting device and the light receiving device are wire-bonded by using gold, silver, aluminum, copper or the like.

### CITATION LIST

[Patent Literature 1] JP H10-209488A

### SUMMARY OF THE INVENTION

In the optical coupling device according to Patent Literature 1, the light emitting device and the light receiving device are sealed with epoxy resin.

On the other hand, there is a case that the light emitting device and the light receiving device are sealed with a silicon-based resin layer in consideration of a resin characteristic and so on. Also, the light emitting device is sometimes connected with the lead frame with an Au wire. In this case, the Au wire is also covered by the silicon-based resin layer.

Here, according to the knowledge by the inventor of the present invention, the adhesion property between the silicon-based resin layer and the Au wire is weak. As a result, a space is sometimes generated between the silicon-based resin layer and the Au wire. The space hinders light transfer.

Other problems and new features will become clear from the description and the attached drawings.

An optical coupling device according to one embodiment includes a first lead frame, a light emitting device installed on the first lead frame, a light receiving device configured to receive light emitted from the light emitting device, a silicon-based resin layer disposed to have a translucent property and to cover the light emitting device, an electrically conductive wire connecting the first lead frame and the light emitting device. The conductive wire is formed of a material which contains silver.

According to the above one embodiment, the optical coupling device is provided which can improve a light transfer rate.

### BRIEF DESCRIPTION OF THE DRAWINGS

FIG. 1 is a sectional view schematically showing an optical coupling device according to a first embodiment;

FIG. 2 is a sectional view schematically showing an optical coupling device according to a comparison example;

FIG. 3 is a sectional view schematically showing the optical coupling device according to the comparison example;

FIG. 4 is a sectional view schematically showing the optical coupling device according to the first embodiment;

FIG. 5 is a sectional view schematically showing the optical coupling device according to a second embodiment;

FIG. 6 is a diagram schematically showing the state of an interface portion between the metal and the silicon-based resin layer;

FIG. 7 is a sectional view schematically showing the optical coupling device according to a reference example 1;

FIG. 8 is a diagram schematically showing the optical coupling device according to a reference example 2;

FIG. 9 is a breakaway view schematically showing the optical coupling device according to a fifth embodiment.

FIG. 10 is a sectional view schematically showing the optical coupling device according to a comparison example to the fifth embodiment;

FIG. 11 is a sectional view schematically showing the optical coupling device according to the comparison example to the fifth embodiment;

FIG. 12 is a sectional view schematically showing the optical coupling device according to the fifth embodiment; and

FIG. 13 is a sectional view schematically showing the optical coupling device according to a sixth embodiment.

### DESCRIPTION OF EMBODIMENTS

Embodiments of an optical coupling device will be described below with reference to the attached drawings.

### First Embodiment

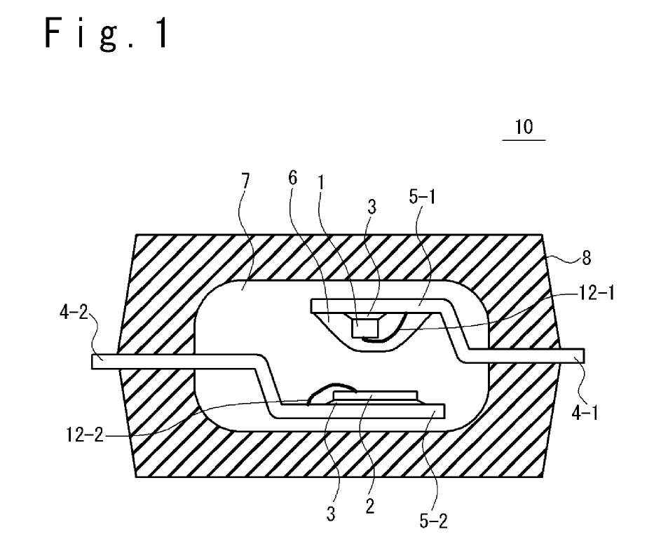

FIG. 1 is a sectional view schematically showing the optical coupling device according to a first embodiment.

As shown in FIG. 1, an optical coupling device 10 contains a light emitting device 1, a light receiving device 2, a first lead frame 4-1, a second lead frame 4-2, a silicon-based resin layer 6, a translucent resin layer 7 and a light-blocking resin layer 8.

The first lead frame 4-1 contains a first opposing region 5-1, and the second lead frame 4-2 contains a second opposing region 5-2. The first lead frame 4-1 and the second lead frame 4-2 are arranged such that the first opposing region 5-1 and the second opposing region 5-2 oppose to each other.

The light emitting device 1 is mounted in the first opposing region 5-1 through an electrically conductive paste 3 (mounting material). The light receiving device 2 is also mounted in the second opposing region 5-2 through an electrically conductive paste 3. The light emitting device 1 is configured of a material such as GaAs and AlGaAs.

The light emitting device 1 is connected to the first lead frame 4-1 through an Ag wire 12-1. The Ag wire 12-1 is an alloy wire that includes Ag of 50 weight % or more in the entire weight of the alloy wire.

The light receiving device 2 is also connected to the second lead frame 4-2 through an Ag wire 12-2, similarly to the light emitting device 1.

The silicon-based resin layer 6 is disposed to protect the light emitting device 1. That is, the silicon-based resin layer 6 is disposed to cover the light emitting device 1. The silicon-based resin layer 6 has a translucent property. Here, the silicon-based resin layer 6 is disposed to perfectly cover the Ag wire 12-1, too. Note that the silicon-based resin layer 6 is a resin layer that includes as a main component, a resin which has a siloxane bond in a main chain.

The translucent resin layer 7 is disposed to cover the silicon-based resin layer 6 and the light receiving device 2. The translucent resin layer 7 contains a resin such as epoxy resin. It is desirable that filler such as silica is mixed up to about 70 weight % for the sakes of strength and flame-proof property, when the epoxy resin is used.

The light-blocking resin layer 8 is disposed to prevent external light from being inputted. The light-blocking resin layer 8 is disposed to cover the translucent resin layer 7. As the light-blocking resin layer 8, a material layer such as black epoxy resin layer is used.

In the above optical coupling device 10, an electrical signal is supplied through the first lead frame 4-1 to the light emitting device 1. The light emitting device 1 emits an optical signal on the basis of the electrical signal. The optical signal emitted from the light emitting device 1 is supplied through the silicon-based resin layer 6 and the translucent resin layer 7 to the light receiving device 2. In the light receiving device 2, the optical signal is converted into an electrical signal and transferred through the second lead frame 4-2 to a destination apparatus (not shown).

Next, a manufacturing method of the above optical coupling device 10 will be described.

At first, the light emitting device 1 is mounted on the first lead frame 4-1 through the electrically conductive paste 3. Similarly, the light receiving device 2 is mounted on the second lead frame 4-2 through the electrically conductive paste 3.

Next, the light emitting device 1 is connected to the first lead frame 4-1 by the Ag wire 12-1. Also, the light receiving device 2 is similarly connected to the second lead frame 4-2 by the Ag wire 12-2.

Next, the silicon-based resin is supplied to cover the light emitting device 1 and the Ag wire 12-1. Consequently, the silicon-based resin layer 6 is formed.

Next, the first lead frame 4-1 and the second lead frame 4-2 are arranged such that the first opposing region 5-1 opposes to the second opposing region 5-2.

Next, the epoxy resin for the translucent resin layer 7 is supplied in such a manner that the light receiving device 2 and the silicon-based resin layer 6 are covered, and then the epoxy resin is hardened. At this time, the epoxy resin is supplied in a high temperature state (for example, 160° C. to 200° C.) and then is cooled.

After that, the epoxy resin as the light-blocking resin layer 8 is supplied to cover the translucent resin layer 7.

Thus, the optical coupling device 10 is obtained.

Here, according to the present embodiment, the light emitting device 1 is covered with the silicon-based resin layer 6. For this reason, the deterioration of the light emitting device 1 can be prevented. Specifically, when the semiconductor such as GaAs and AlGaAs is used for the light emitting device 1, there is a case that the application of stress causes the light emission property to be deteriorated. The silicon-based resin layer 6 is high in flexibility, as compared with the epoxy resin layer. According to the present embodiment, because the light emitting device 1 is covered with the silicon-based resin layer 6, the stress is relaxed so as to prevent the deterioration of the light emitting device 1.

It is preferable that the content of the filler (such as silica) in the silicon-based resin layer 6 is 20 weight % or less. Also, it is more preferable that the filler is not contained in the silicon-based resin layer 6. The silicon-based resin is a liquid resin. When the content of the filler exceeds 20 weight %, the flexibility (liquidity) of the silicon-based resin layer 6 decreases. As a result, there is a case that the silicon-based resin layer 6 cannot be formed in a portion around the light emitting device 1 at a time of manufacturing. Also, when the content of the filler exceeds 20 weight %, the hardness of the silicon-based resin layer 6 becomes high. Thus, it becomes difficult to sufficiently relax the stress applied to the light emitting device 1.

Moreover, according to the present embodiment, because the Ag wire 12 is used, a high light transfer rate can be obtained. This point will be described below.

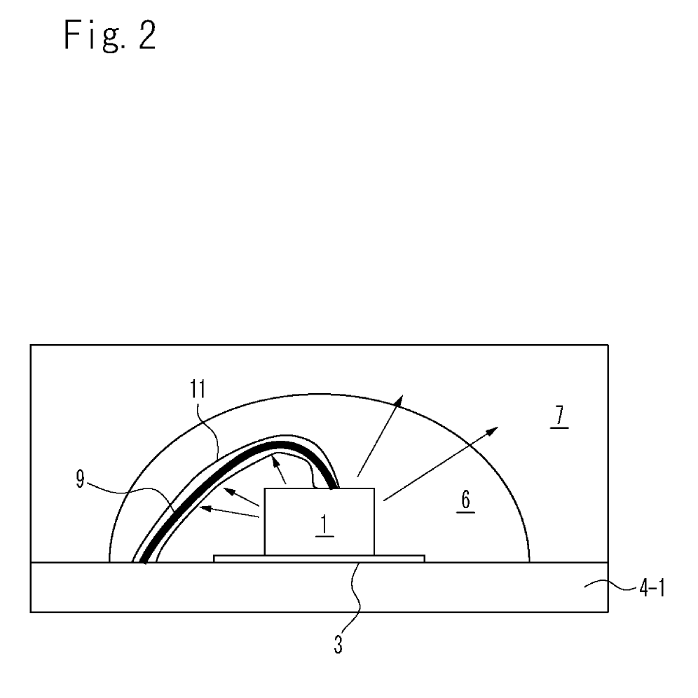

For a comparison with the optical coupling device 10 according to the present embodiment, the optical coupling device 10 according to a comparison example will be described. FIG. 2 is a sectional view schematically showing the optical coupling device according to the comparison example. In the optical coupling device 10 according to the comparison example, the light emitting device 1 and the first lead frame 4-1 are connected to each other by an Au wire 9 and not the Ag wire 12-1. The other constituents are assumed to be similar to those of the optical coupling device 10 according to the present embodiment shown in FIG. 1.

The bond between the resin and the metal is mainly hydrogen bond. Au is the most difficult to form the hydrogen bond among the metals. Thus, adhesion force between the Au wire 9 and the silicon-based resin layer 6 becomes weak. As a result, as shown in FIG. 2, in the optical coupling device 10 according to the comparison example, the silicon-based resin layer 6 becomes easy to delaminate from the Au wire 9, and a space 11 is easy to generate between the silicon-based resin layer 6 and the Au wire 9. The gap 11 absorbs the light and prevents the light transfer or propagation.

On the contrary, the Ag wire 12-1 used in the present embodiment is greater in the adhesion force to the silicon-based resin than the Au wire 9. This is because Ag is easy to be oxidized and sulfurated as compared with Au, so that the hydrogen bond to the silicon-based resin group is easy to generate. Actually, the inventor of the present invention performed an experiment of the adhesion property, in which the silicon-based resin was coated on each of the Ag wire and the Au wire and hardened. Then, the presence or absence of a gap between each wire and the silicon-based resin was observed. As a result, when the Au wire was used, the gap was observed between the Au wire and the silicon-based resin. However, when the Ag wire was used, any gap was not observed. Also, when the content of Ag in the Ag wire was 50 weight % or more, the adhesion force of a degree to which the generation of the gap could be effectively prevented was obtained. Thus, the generation of the gap 11 is prevented between the silicon-based resin layer 6 and the Ag wire 12-1.

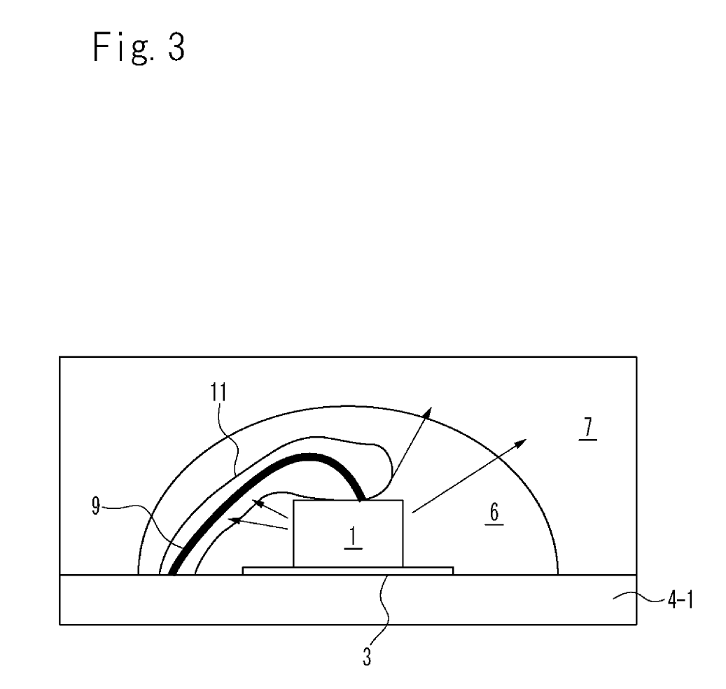

There is a case that the size of gap 11 is increased during the manufacturing the optical coupling device 10. As mentioned already, the filler is preferred to be mixed in the translucent resin layer 7 (epoxy resin), for the sakes of the strength and the flame-proof property. When the filler is mixed, a thermal expansion coefficient is made low (for example, about 22 ppm). On the other hand, a thermal expansion coefficient of the silicon-based resin layer 6 is large (for example, about 400 ppm). As mentioned above, when the translucent resin layer 7 is formed, the epoxy resin is supplied in the high temperature state (about 160° C. to 200° C.). After that, it is cooled to a room temperature (about 25° C.). At this time of cooling, the silicon-based resin layer 6 greatly contracts due to a difference in the thermal expansion coefficient, as compared with the translucent resin layer 7. As a result, as shown in FIG. 3, the delamination of the silicon-based resin layer 6 from the Au wire 9 is promoted, and the size of gap 11 is increased. Consequently, the light transfer rate is further deteriorated.

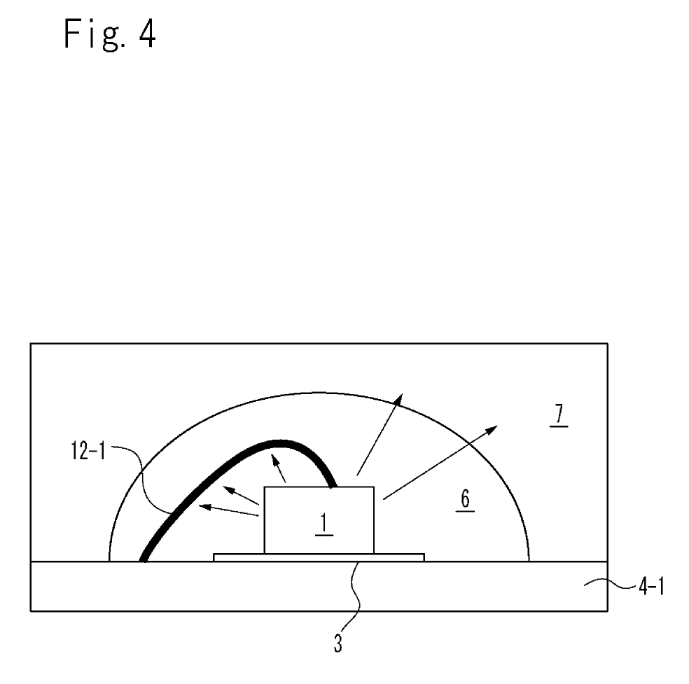

On the contrary, as shown in FIG. 4, according to the present embodiment, because the Ag wire 12-1 is used, the silicon-based resin layer 6 is not delaminated, and the gap 11 is not generated. For this reason, even when the translucent resin layer 7 is formed, the delamination is not promoted, so as to prevent the deterioration in the light transfer rate.

Moreover, according to the present embodiment, even from the viewpoint of a light reflectivity of the Ag wire 12-1, the light transfer rate can be improved. That is, Ag is high in the light reflectivity, as compared with other metal materials such as Au and Cu. Specifically, when the light wavelength is 700 nm, the light reflectivity of Au is 97.0, the light reflectivity of Ag is 98.5 and the light reflectivity of Cu is 97.5. Also, when the light wavelength is 1000 nm, the light reflectivity of Au is 98.2, the light reflectivity of Ag is 98.9 and the light reflectivity of Cu is 98.5. The high light reflectivity makes it possible for the light emitted from the light emitting device 1 to easily arrive at the light receiving device 2. As a result, the light transfer rate can be improved. That is, according to the present embodiment, the light transfer rate can also be improved from the viewpoint of the light reflectivity.

Also, in case that the semiconductor material such as GaAs and AlGaAs is used for the light emitting device 1 and a Cu is used for the wire, the light emission rate of the light emitting device 1 is known to decrease with time elapsed. On the contrary, when the Ag wire 12-1 is used, the light emission rate does not decrease even in case that it is kept for a long time.

As mentioned above, according to the present embodiment, the light transfer or propagation rate can be improved. A high-speed operation and a high current transfer rate are required in the optical coupling device 10. According to the present embodiment, in order to improve the light transfer rate, a current transfer rate required to the optical coupling device 10 can be attained at an initial time or when the optical coupling device 10 is stored for a long time.

Also, in the present embodiment, as shown in FIG. 4, the Ag wire 12-1 is perfectly covered with the silicon-based resin layer 6. On the other hand, in the optical coupling device 10 described in the Patent Literature 1 (JP H10-209488A), the resin layer that covers the light emitting device does not perfectly cover the wire which is connected to the light emitting device. That is, the wire is arranged to intersect an interface between different resin layers.

If the Ag wire 12-1 is arranged to intersect the interface between the silicon-based resin layer 6 and the translucent resin layer 7 (the epoxy resin layer), the Ag wire 12-1 is easy to break when a temperature cycle test is performed. As mentioned above, the adhesion force between the Ag wire 12-1 and the silicon-based resin layer 6 is high. Also, the Ag wire 12-1 is strongly fixed to the silicon-based resin layer 6. Similarly, the adhesion force between the Ag wire 12-1 and the translucent resin layer 7 is high. Thus, the Ag wire 12-1 is strongly fixed to the translucent resin layer 7. In the temperature cycle test, the silicon-based resin layer 6 and the translucent resin layer 7 are thermally expanded or thermally contracted. When the Ag wire 12-1 is fixed to both of the silicon-based resin layer 6 and the translucent resin layer 7, the difference in the thermal expansion rate between the silicon-based resin layer 6 and the translucent resin layer 7 causes a great force to be applied to the Ag wire 12-1. For this reason, the Ag wire 12-1 is easy to break through the heating.

On the contrary, in the present embodiment, the Ag wire 12-1 is perfectly or fully covered with the silicon-based resin layer 6. That is, the Ag wire 12-1 does not intersect the interface. Thus, even when the temperature cycle test is performed, it can be prevented that the force due to the difference in the thermal expansion rate is applied to the Ag wire 12-1. Therefore, the break of the wire is prevented.

Note that when the Au wire 9 is used, the adhesion property is weak, so that the Au wire 9 is not strongly fixed to the silicon-based resin layer 6. Thus, it is not necessary to consider the break of the wire in the temperature cycle test. That is, in the present embodiment, because the Ag wire 12-1 is used and the silicon-based resin layer 6 is used, the Ag wire 12-1 is desired to be perfectly covered with the silicon-based resin layer 6.

Note that in the present embodiment, the case in which the silicon-based resin layer 6 covers the light emitting device 1 and does not cover the light receiving device 2 has been described. However, the silicon-based resin layer 6 may cover not only the light emitting device 1 but also the light receiving device 2.

### Second Embodiment

Next, a second embodiment will be described.

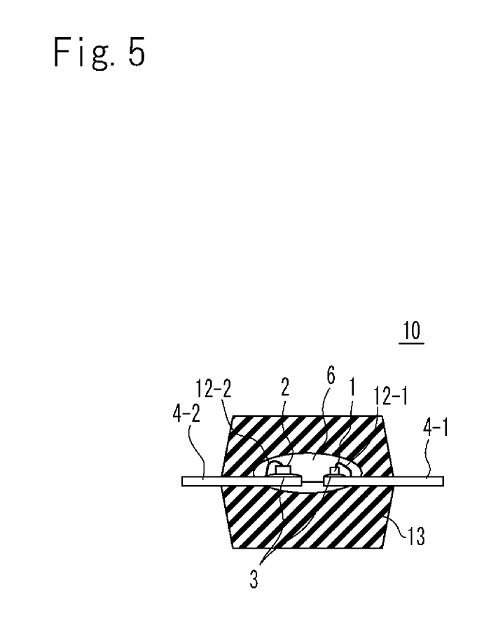

FIG. 5 is a sectional view schematically showing the optical coupling device 10 according to the present embodiment. In the first embodiment, the first opposing region 5-1 and the second opposing region 5-2 are arranged to oppose to each other. On the contrary, in the present embodiment, as shown in FIG. 5, a mount portion (a first mount region) of the light emitting device 1 on the first lead frame 4-1 and a mount portion (second mount region) of the light receiving device 2 on the second lead frame 4-2 are arranged on a same flat plane. Also, in the present embodiment, the silicon-based resin layer 6 is provided to cover not only the light emitting device 1 but also the light receiving device 2. Moreover, the silicon-based resin layer 6 is covered with a disturbance light-blocking resin layer 13. That is, the optical coupling device 10 according to the present embodiment is a so-called reflection type single mold photo coupler. Because the configuration similar to the first embodiment can be employed regarding the other constituents, the detailed description is omitted.

As shown in FIG. 5, also in the present embodiment, the light emitting device 1 is connected through the Ag wire 12-1 to the first lead frame 4-1. Also, the light receiving device 2 is connected through the Ag wire 12-2 to the second lead frame. The silicon-based resin layer 6 is provided to perfectly cover the light emitting device 1, the light receiving device 2, the Ag wire 12-1 and the Ag wire 12-2.

In the present embodiment, an optical signal outputted from the light emitting device 1 is supplied to the light receiving device 2 directly or through reflection by the disturbance light-blocking resin layer 13.

In the present embodiment, the Ag wire 12-2 is used as the wire between the light receiving device 2 and the second lead frame 4-2, which can further improve the light transfer rate.

Note that in the present embodiment, the case in which the silicon-based resin layer 6 covers both of the light emitting device 1 and the light receiving device 2 has been described. However, even in case that the silicon-based resin layer 6 covers the light emitting device 1 and does not cover the light receiving device 2, the present embodiment can be applied.

### Third Embodiment

Next, a third embodiment will be described. In the present embodiment, the material of disturbance light-blocking resin layer 13 will be described. Because the configuration similar to that of the second embodiment can be adopted for other constituents, the detailed description is omitted.

In the present embodiment, a layer in which titanium oxide is mixed in a resin (e.g. epoxy resin) is used as the disturbance light-blocking resin layer 13. The reflectivity of the light outputted from the light emitting device 1 can be improved by mixing the titanium oxide. The light emitted from the light emitting device 1 is prevented from being absorbed by the disturbance light-blocking resin layer 13 and the light transfer rate can be further improved.

On the other hand, the disturbance light-blocking resin layer 13 may be formed to absorb light. For example, the disturbance light-blocking resin layer 13 which absorbs light can be accomplished by mixing carbon black in a resin (e.g. epoxy resin). When the disturbance light-blocking resin layer 13 is formed to absorb the light, external light can be surely prevented from transmitting through the disturbance light-blocking resin layer 13 and the reliability of the optical coupling device can be improved.

### Fourth Embodiment

Next, a fourth embodiment will be described. In the present embodiment, a composition of the silicon-based resin layer 6 is devised. Because the other configuration is similar to those of the above-mentioned embodiments, the detailed description is omitted.

In the present embodiment, the silicon-based resin layer 6 has a compound which contains a siloxane bond and a hydroxyl group. Specifically, the silicon-based resin layer 6 contains a compound (glue component) containing the siloxane bond and the hydroxyl group, in addition to a resin component having siloxane bond in a main chain as a main component. Note that the resin component itself having the siloxane bond in the main chain as the main component may contain the hydroxyl group in its molecule. In this case, the main component itself acts as the compound containing the siloxane bond and the hydroxyl group.

According to the present embodiment, the adhesion force between the silicon-based resin layer 6 and the Ag wire 12-1 can be more increased. This point will be described below.

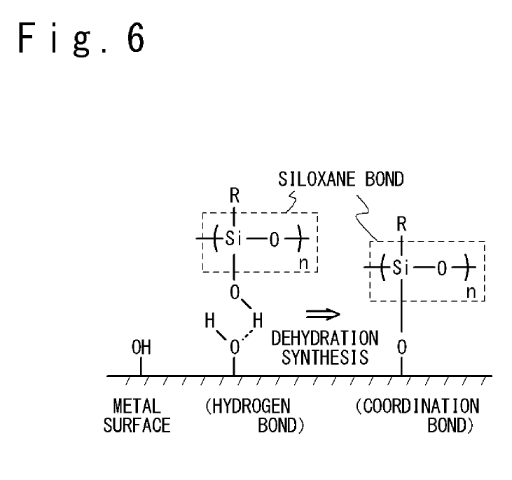

FIG. 6 is a diagram schematically showing the structure of an interface between a metal and the silicon-based resin layer 6. It should be noted that R is a group in FIG. 6. Ag is in a state to be easy to be oxidized as compared with Au. An OH group is coupled to the oxidized metal surface. The OH group on the metal surface forms the hydrogen bond with the hydroxyl group (the OH group) contained in the silicon-based resin layer 6. Moreover, there is a case that the hydrogen bond is changed to a coordination bond through the dehydration synthesis. In the present embodiment, it is expected that the hydrogen bond and the coordination bond are mixed in the interface between the Ag wire 12-1 and the silicon-based resin layer 6.

The binding energy of the hydrogen bond is about 0.2 eV whereas the binding energy of the coordination bond is 1 to 2 eV. That is, the coordination bond is formed so that high adhesion force is obtained. According to the present embodiment, because the silicon-based resin layer 6 has the compound containing the siloxane bond and the hydroxyl group, the silicon-based resin layer 6 and the Ag wire 12-1 are firmly coupled by the hydrogen bond and the coordination bond. Thus, the high adhesion force is obtained.

It should be noted that because Au is most difficult to be oxidized among the metals, the hydrogen bond and the coordination bond (—O—) are difficult to be formed. On the other hand, Ag is easy to be oxidized and sulfurated, and the hydrogen bond and the combination bond (—O—) are easy to be formed, as compared with Au. That is, in the present embodiment, because the Ag wire 12-1 is used as a conductive wire, the coordination bond becomes easy to be formed between the Ag wire 12-1 and the silicon-based resin layer 6. According to the present embodiment, adhesion force between the conductive wire and the silicon-based resin layer 6 is improved from this viewpoint.

### Fifth Embodiment

Next, a fifth embodiment will be described. In the present embodiment, the structure of a first lead frame 4-1 is devised to the previously mentioned embodiments.

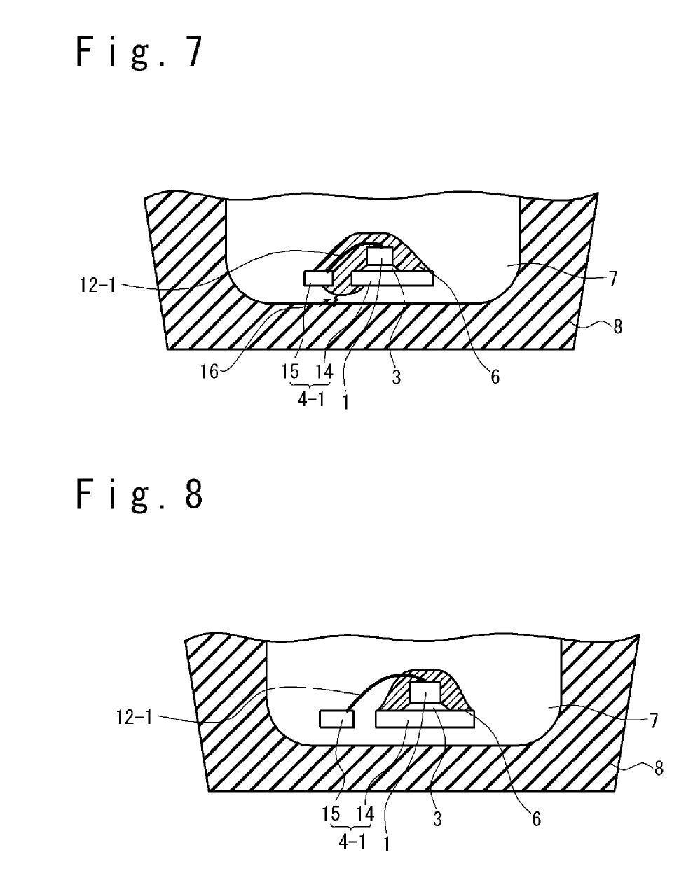

An optical coupling device according to a reference example to the present embodiment will be described before the optical coupling device according to the present embodiment will be described. FIG. 7 is a sectional view schematically showing the optical coupling device according to a reference example 1.

As shown in FIG. 7, in the optical coupling device, generally, the first lead frame 4-1 has a first part 14 and a second part 15. The first part 14 and the second part 15 are arranged on a same plane. The light emitting device 1 is put on the surface of the first part 14. The Ag wire 12-1 is connected with the surface of the second part 15 in one end and is connected with the light emitting device 1 at the other end.

Here, the first part 14 and the second part 15 must be electrically insulated. Therefore, the first part 14 and the second part 15 are isolating from each other.

The silicon-based resin layer 6 covers the Ag wire 12-1 fully. Specifically, the silicon-based resin layer 6 is arranged on the first lead frame 4-1 to cover a region between the first part 14 and the second part 15. It should be noted that the silicon-based resin layer 6 is covered with the translucent resin layer 7, which is covered with the light-blocking resin layer 8.

It should be noted that the structure similar to that of the first embodiment is adopted with respect to the other points.

Here, the silicon-based resin layer 6 is supplied onto the first lead frame 4-1 to cover the Ag wire 12-1 and the light emitting device 1 in case of manufacturing the optical coupling device. At this time, there is a case that the silicon-based resin layer 6 goes around to the back side of the first lead frame 4-1 through the gap between the first part 14 and the second part 15.

When the silicon-based resin layer 6 goes around to the back side, the translucent resin layer 7 has become thin partially. As a result, when a reflow test is carried out, it becomes easy for a crack 16 to be formed in the translucent resin layer 7. Especially, according to the knowledge of the inventor, a crack 16 becomes easy to generate when the thickness of translucent resin layer 7 becomes equal to or less than 30·m.

In the optical coupling device, the light emitting device 1 and the light receiving device 2 must be separated from each other in some degree in order to secure insulation property between the light emitting device 1 and the light receiving device 2. On the other hand, the thinness of the package is required to the optical coupling device. That is, it is required to make the translucent resin layer 7 thin. Therefore, when the silicon-based resin layer 6 goes around to the back side, it is easy for the translucent resin layer 7 to be made thin to an extent that the crack 16 generates.

In order to prevent that the silicon-based resin layer 6 goes around to the back side, it is considered that the silicon-based resin layer 6 is provided only on the first part 14. FIG. 8 is a diagram schematically showing the optical coupling device according to a reference example 2. In this reference example, the silicon-based resin layer 6 is provided on the first part 14 but is not provided on the second part 15. It should be noted that such a structure is adopted even in Patent Literature 1 (JP H10-209488A).

According to the optical coupling device of the reference example 2, it can be prevented that the silicon-based resin layer 6 goes around to the back side. However, in the optical coupling device according to the reference example 2, the Ag wire 12-1 intersects the interface between the translucent resin layer 7 and the silicon-based resin layer 6 necessarily. As a result, as described in the above-mentioned embodiments, it becomes easy for the Ag wire 12-1 to be broken.

Therefore, in the optical coupling device according to the present embodiment, an interval between the first part 14 and the second part 15 is devised.

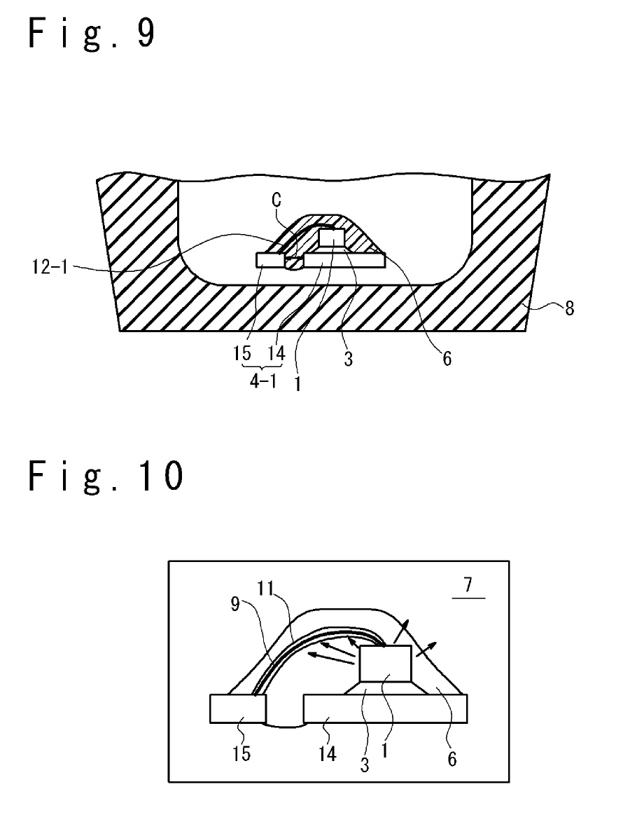

FIG. 9 is a sectional view schematically showing the optical coupling device according to the present embodiment. In the present embodiment, as shown in FIG. 9, the interval c between the first part 14 and the second part 15 is set to such a size as the silicon-based resin layer 6 does not go around to the back side at the time of the supply of the silicon-based resin layer 6 or for a time period from the supply of the silicon-based resin layer 6 to the hardening. The structure similar to that of the optical coupling device according to the reference example 1 which is shown in FIG. 7 is adopted with respect to the other points.

By adopting the structure as shown in FIG. 9, it is possible to cover the Ag wire 12-1 fully with the silicon-based resin layer 6 while the silicon-based resin layer 6 is prevented from goes around to the back side.

It should be noted that a specific size of an interval c between the first part 14 and the second part 15 depends on the fluidity of the silicon-based resin layer 6. For example, the size of the interval c is “t+0.05 mm” or less when the thickness of the first lead frame (the first part 14 and the second part 15) is “t”.

Next, a manufacturing method of the optical coupling device according to the present embodiment will be described.

Like the first embodiment, the light emitting device 1 is mounted or installed through a conductive paste 3 on the first lead frame 4-1 (the first part 14) in the present embodiment. In the same way, the light receiving device 2 is installed on the second lead frame 4-2 through the conductive paste 3.

Next, the light emitting device 1 is connected with the first lead frame 4-1 (the second part 15) by the Ag wire 12-1. In the same way, the light receiving device 2 is connected with the second lead frame 4-2 by the Ag wire 12-2.

Next, the silicon-based resin is supplied to cover the light emitting device 1 and the Ag wire 12-1. Thus, the silicon-based resin layer 6 is formed. At this time, in the present embodiment, because the size of the interval c between the first part 14 and the second part 15 is devised, the silicon-based resin layer 6 does not go around to the back side.

After that, like the first embodiment, the first lead frame 4-1 and the second lead frame 4-2 are arranged to partially oppose to each other, and the translucent resin layer 7 is supplied and hardened. Moreover, the light-blocking resin layer 8 is supplied to cover the translucent resin layer 7.

In this way, the optical coupling device 10 is obtained.

According to the present embodiment, because the size of the interval c between the first part 14 and the second part 15 is devised, the silicon-based resin layer 6 is prevented from going around to the back side. Thus, it is possible to prevent a crack from being generated in the translucent resin layer 7, and to improve the reliability of the optical coupling device more.

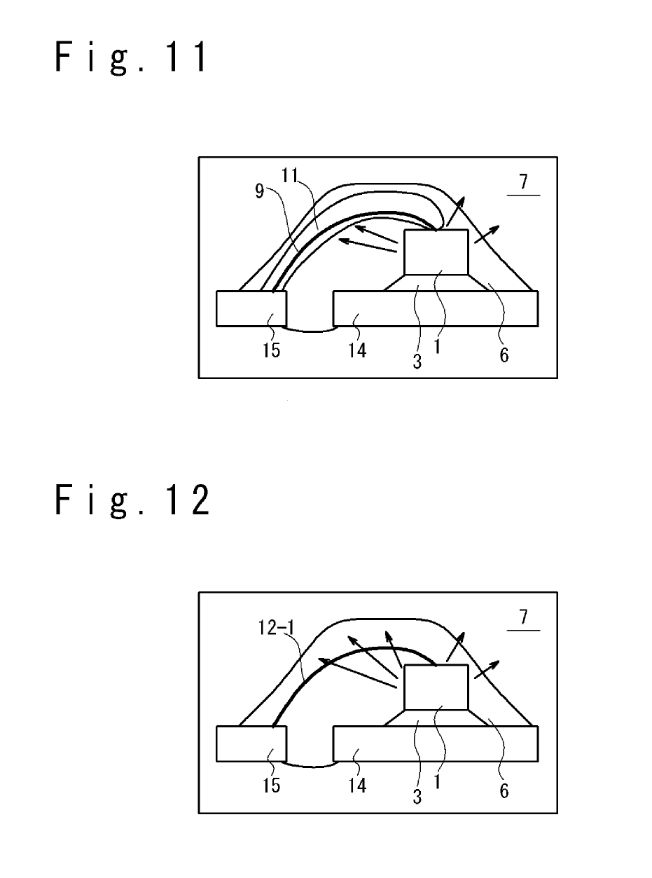

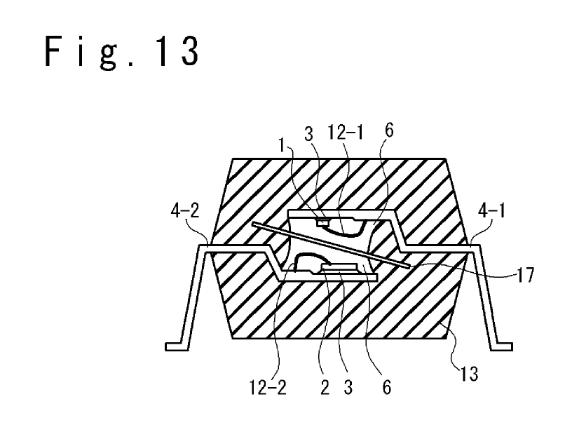

Also, in the present embodiment, because the Ag wire 12-1 is covered with the silicon-based resin layer 6, the same operation and effect as the above-mentioned embodiments can be obtained. FIG. 10 and FIG. 11 are sectional views schematically showing the optical coupling device according to comparison examples to the present embodiment. In this comparison example, an Au wire 9 is used as a conductive wire. Other points are same as those in the present embodiment. In the optical coupling device according to this comparison example, because the adhesion force between the Au wire 9 and the silicon-based resin layer 6 is small, a space 11 is easy to be generated between the Au wire 9 and the silicon-based resin layer 6. The size of the space 11 is sometimes increased during a manufacturing process, as described in the first embodiment (see FIG. 11). As a result, a light transfer rate is sometimes aggravated. On the other hand, according to the optical coupling device according to the present embodiment, as shown in FIG. 12, because the Ag wire 12-1 used, the adhesion force between the conductive wire and the silicon-based resin layer 6 is large, so that the space 11 is difficult to be generated. Thus, the light transfer rate can be improved.

It should be noted that as a technique to connect the light emitting device 1 and first lead frame 4-1 (the second part 15) by using the Ag wire 12-1, the following methods are used.

First, the Ag wire 12-1 is supported by using a capillary (not shown). Then, the tip of Ag wire 12-1 is heated and a first ball is formed. For example, the first ball is formed with a high voltage applied between the Ag wire 12-1 and an electrode (not shown) and a current flowing through a path between the electrode and the Ag wire 12-1.

In case of using the Ag wire 12-1, it is difficult to form the first ball appropriately. However, the first ball with an appropriate size can be formed by controlling a flow rate of nitrogen gas under a nitrogen atmosphere, according to the knowledge of the inventor of the present invention.

After forming the first ball, the tip of Ag wire 12-1 is brought into contact with one of the pads for the light emitting device 1 and the second part 15, and heat, load and supersonic are applied to the contact portion. After that, the other end of the Ag wire 12-1 is connected with the other pad of the pads for the light emitting device 1 and the second part 15 by the capillary (not shown).

Here, the rigidity of Ag wire 12-1 is larger by about 20% than a typical Au wire used as the conductive wire. Therefore, the capillary having the same shape as the capillary for the Au wire can be used. Also, the bonding can be stably carried out by using the same conditions as those of the Au wire with respect to a temperature condition, a load condition and a US (ultrasonic) condition.

Also, Al, Au, Ag, Cu, and so on can be used as the material of the pads of the light emitting device 1 or the second part 15. According to the knowledge of the inventor, even if the material of the pad is either of these metals, there is no problem when the Ag wire 12-1 is connected with the pad.

Also, when the material of the pad is Al, it is worried that humidity resistance of an alloy layer of the Ag wire 12-1 and the Al pad is degraded. However, according to the knowledge of the inventor, it was confirmed that the humidity resistance examination (85° C. and 85%) for 3000 hours to an actually delivered device was passed, by devising a forming method of the Ag—Al alloy layer.

### Sixth Embodiment

Next, a sixth embodiment will be described.

FIG. 13 is a sectional view schematically showing the optical coupling device according to the present embodiment. As shown in FIG. 13, in the present embodiment, a translucent insulating film 17 is arranged between the light emitting device 1 and the light receiving device 2. For example, as the insulating film 17, a polyimide-based insulating film can be used.

Also, like the above-mentioned embodiment, the light emitting device 1 is connected with the first lead frame 4-1 through the Ag wire 12-1. Also, the light receiving device 2 is connected with the second lead frame 4-2 through the Ag wire 12-2.

It should be noted that in the first embodiment, a case where the silicon-based resin layer 6 is covered with the translucent resin layer 7 has been described (see FIG. 1). That is, in the first embodiment, the light emitted from the light emitting device 1 is incident to the light receiving device 2 through the silicon-based resin layer 6 and the translucent resin layer 7.

On the other hand, in the present embodiment, the silicon-based resin layer 6 is provided to cover the light receiving device 2 in addition to the light emitting device 1, as shown in FIG. 13. Specifically, the silicon-based resin layer 6 is provided to cover the light emitting device 1, the light receiving device 2, the Ag wire 12-1 and the Ag wire 12-2 fully. Moreover, the silicon-based resin layer 6 is covered with a disturbance light-blocking resin layer 13. That is, the optical coupling device according to the present embodiment is an opposing-type single mold photo-coupler.

Note that because the same structure as that of the first embodiment can be adopted about the other points, the detailed description will be omitted.

In the present embodiment, the light emitted from the light emitting device 1 is incident on the light receiving device 2 directly or after being reflected by the disturbance light-blocking resin layer 13 (the light-blocking layer). Here, because the Ag wire 12-1 is used as the conductive wire like the above-mentioned embodiments and the Ag wire 12-1 is covered with the silicon-based resin layer 6, the light transfer rate can be improved.

In addition, according to the present embodiment, because the insulating film 17 is provided, it is possible to improve the insulation performance between the light emitting device 1 and the light receiving device 2.

Also, because the Ag wire 12-2 is used as the conductive wire which connects the light receiving device 2 and the second lead frame 4-2, the light transfer rate can be improved more.

It should be noted that in the present embodiment, an example that the silicon-based resin layer 6 covers both of the light emitting device 1 and the light receiving device 2 has been described. However, even if the silicon-based resin layer 6 covers the light emitting device 1 but does not cover the light receiving device 2, the present embodiment can be applied. That is, even if the translucent resin layer 7 is provided to cover the silicon-based resin layer 6 like the first embodiment, the present embodiment can be applied.

Also, in the present embodiment, like the

What is claimed is:

1. An optical coupling device comprising:
a first lead frame;
a light emitting device installed on the first lead frame;
a light receiving device configured to receive an optical signal outputted from the light emitting device;
a translucent silicon-based resin layer disposed to cover the light emitting device; and
a conductive wire disposed to connect the first lead frame and the light emitting device,
wherein the conductive wire is formed of a material which contains silver.

2. The optical coupling device according to claim 1, wherein the silicon-based resin layer is disposed to cover the conductive wire fully.

3. The optical coupling device according to claim 1, wherein the conductive wire contains silver of 50 weight % or more.

4. The optical coupling device according to claim 1, wherein the silicon-based resin layer is disposed to cover the light emitting device and the light receiving device.

5. The optical coupling device according to claim 1, further comprising:
a second lead frame on which the light receiving device is installed,
wherein the first lead frame has a first opposing region, and the second lead frame has a second opposing region,
wherein the first lead frame and the second lead frame are arranged such that the first opposing region opposes to the second opposing region, and
wherein the light emitting device is installed in the first opposing region, and the light receiving device is installed in the second opposing region.

6. The optical coupling device according to claim 1, further comprising:
a second lead frame on which the light receiving device is installed,
wherein the first lead frame has a first installation region on which the light emitting device is installed,
wherein the second lead frame has a second installation region on which the light receiving device is installed, and
wherein the first lead frame and the second lead frame are arranged such that the first installation region and the second installation region are located on a same plane.

7. The optical coupling device according to claim 1, further comprising:
a light-blocking layer disposed to cover the silicon-based resin layer and to reflect light emitted from the light emitting device.

8. The optical coupling device according to claim 1, further comprising:
a light-blocking layer disposed to cover the silicon-based resin layer and to absorb light.

9. The optical coupling device according to claim 1, wherein the silicon-based resin layer has a compound which contains a siloxane bond and a hydroxyl group.

10. The optical coupling device according to claim 1, wherein the first lead frame comprises a first part and a second part,
wherein the first part and the second part are arranged on a same plane to be separated from each other,
wherein the light emitting device is disposed on a surface of the first part,
wherein the conductive wire is connected with a surface of the second part at one end and is connected with the light emitting device at the other end,
wherein the silicon-based resin layer is disposed on the first part surface and the second part surface to cover a region between the first part and the second part, and
wherein an interval between the first part and the second part has a size by which the silicon-based resin layer does not go around to back sides of the first part and the second part at a time of supply of the silicon-based resin layer or during a period from the supply to a hardening.

11. The optical coupling device according to claim 1, further comprising:
a polyimide-based insulating film disposed between the light emitting device and the light receiving device.
